(19) United States
(12) Patent Application Publication
(10) Pub. No.: US 2007/0119583 A1
(43) Pub. Date: May 31, 2007

(54) Heat sink for distributing a thermal load

(76) Inventors: Jimmy G. Foster SR., Morrisville, NC (US); Donna C. Hardee, Raleigh, NC (US); Don S. Keener, Apex, NC (US); Robert R. Wolford, Raleigh, NC (US)

Correspondence Address: IBM (RPS-BLF);c/o BIGGERS & OHANIAN, LLP, P.O. BOX 1469, AUSTIN, TX, 78767-1469, US

(21) Appl. No.: 11/289,025

(22) Filed: Nov. 29, 2005

(51) Int. Cl. H05K 7/20

(52) U.S. Cl. 165/185; 165/104.33; 361/700; 257/715

(57) ABSTRACT

A heat sink for distributing a thermal load is disclosed that includes a bottom plate, a top plate, a right plate, and a left plate, the plates connected along edges so as to define a space generally cubical in shape with four closed sides and two open ends; heat-dissipating fins connected to each plate, the fins spaced apart in parallel and extending from each plate towards a central axis of the heat sink; and a thermal transport connected to the plate receiving the thermal load and to at least one of the other plates so as to distribute the thermal load among the plates of the heat sink.

### BACKGROUND OF THE INVENTION

1. Field of the Invention

The field of the invention is heat sinks for distributing a thermal load.

2. Description of Related Art

The development of the EDVAC computer system of 1948 is often cited as the beginning of the computer era. Since that time, users have relied on computer systems to simplify the process of information management. Today's computer systems are much more sophisticated than early systems such as the EDVAC. Such modern computer systems deliver powerful computing resources to provide a wide range of information management capabilities through the use of computer software such as database management systems, word processors, spreadsheets, client/server applications, web services, and so on.

In order to deliver powerful computing resources, computer system designers must design powerful computer processors. Current computer processors, for example, are capable of executing billions of computer program instructions per second. Operating these computer processors requires a significant amount of power, and often such processors can consume over 100 watts. Consuming significant amounts of power generates a considerable amount of heat. Unless the heat is removed, heat generated by a computer processor may degrade or destroy the processor's functionality.

To prevent the degradation or destruction of a computer processor, a computer architect may remove heat from the processor by using heat sinks, fans, heat pipes, or even refrigeration systems. Current heat sinks, however, only provide one or two cooling surfaces with attached fins for dissipating the heat absorbed by the heat sinks. Such heat sinks are often unable to remove the heat necessary to prevent damage to today's computer processors because physical limitations may prevent a system designer from designing cooling surface large enough or fins tall enough to dissipate the required amount of heat from the processor. Combining a fan with a heat sink may improve the ability to remove heat from the computer processor, but such a combination also may not be sufficient to prevent damage in today's computer processors. Heat pipes are capable of removing large quantities of heat from a computer processor, but heat pipes may not be an option where a system designer requires a local cooling solution. Refrigeration systems also effectively remove heat, but such systems are typically large and expensive.

### SUMMARY OF THE INVENTION

A heat sink for distributing a thermal load is disclosed that includes a bottom plate, a top plate, a right plate, and a left plate, the plates connected along edges so as to define a space generally cubical in shape with four closed sides and two open ends; heat-dissipating fins connected to each plate, the fins spaced apart in parallel and extending from each plate towards a central axis of the heat sink; and a thermal transport connected to the plate receiving the thermal load and to at least one of the other plates so as to distribute the thermal load among the plates of the heat sink.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a perspective view of an exemplary heat sink for distributing a thermal load according to embodiments of the present invention.

FIG. 2 sets forth a perspective view of a further exemplary heat sink for distributing a thermal load according to embodiments of the present invention.

FIG. 3 sets forth a perspective view of a further exemplary heat sink for distributing a thermal load according to embodiments of the present invention.

FIG. 4 sets forth a perspective view of a further exemplary heat sink for distributing a thermal load according to embodiments of the present invention.

FIG. 5 sets forth a perspective view of a further exemplary heat sink for distributing a thermal load according to embodiments of the present invention.

FIG. 6 sets forth a perspective view of a further exemplary heat sink for distributing a thermal load according to embodiments of the present invention.

FIG. 7 sets forth a perspective view of a further exemplary heat sink for distributing a thermal load according to embodiments of the present invention.

### DETAILED DESCRIPTION OF EXEMPLARY EMBODIMENTS

### Detailed Description

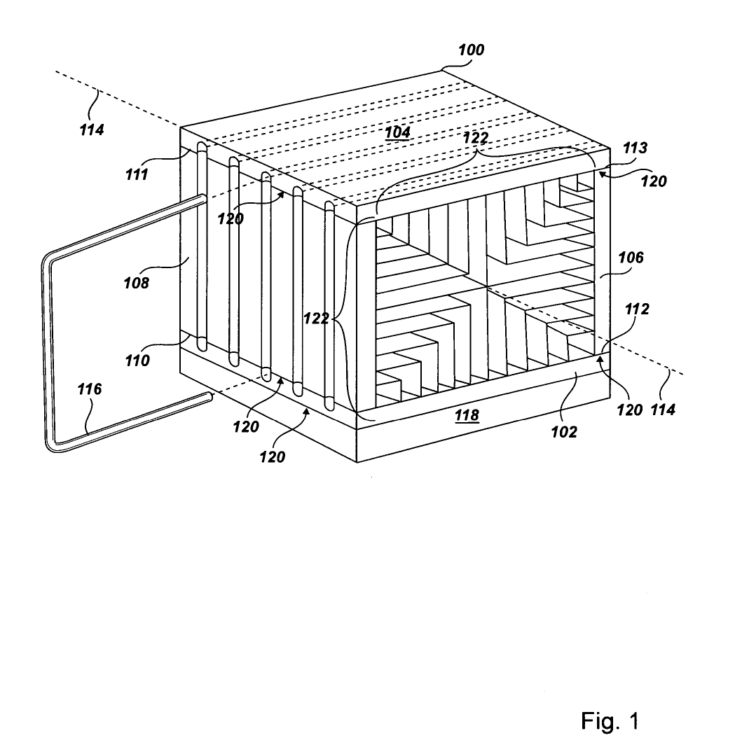

Exemplary heat sinks for distributing a thermal load according to embodiments of the present invention are described with reference to the accompanying drawings, beginning with FIG. 1. FIG. 1 sets forth a perspective view of an exemplary heat sink (100) for distributing a thermal load according to embodiments of the present invention. The thermal load is the rate of thermal energy produced over time from the operation of an integrated circuit package (118) such as, for example, a computer processor or memory chip and is typically expressed in units of Watts.

In the example of FIG. 1, the heat sink (100) is a thermal conductor configured to absorb and dissipate the thermal load from the integrated circuit package (118) thermally connected with the heat sink (100). Thermal conductors used in designing the heat sink (100) may include, for example, aluminum, copper, silver, aluminum silicon carbide, or carbon-based composites. Heat sink (100) absorbs the thermal load from the integrated circuit package through thermal conduction. When thermally connecting the heat sink (100) to the integrated circuit package (118), the heat sink provides additional thermal mass, cooler than the integrated circuit package (118), into which the thermal load may flow. After absorbing the thermal load, the heat sink (100) dissipates the thermal load through thermal convection and thermal radiation into the air surrounding the heat sink (100). Increasing the surface area of the heat sink (100) typically increases the rate of dissipating the thermal load.

Heat sink (100) in the example of FIG. 1 connects to the integrated circuit package (118) by a thermal interface (120). The thermal interface (120) is a thermally conductive material that reduces the thermal resistance associated with transferring the thermal load from the integrated circuit package (118) to the heat sink (100). The thermal interface (120) between the integrated circuit package (118) and the heat sink (100) has less thermal resistance than could typically be produced by connecting the integrated circuit package (118) directly to the heat sink (100). Decreasing the thermal resistance between the integrated circuit package (118) and the heat sink (100) increases the efficiency of transferring the thermal load from the integrated circuit package (118) to the heat sink (100). The thermal interface (120) in the example of FIG. 1 may include non-adhesive materials such as, for example, thermal greases, phase change materials, and gap-filling pads. The thermal interface (120) may also include adhesive materials such as, for example, thermosetting liquids, pressure-sensitive adhesive (‘PSA’) tapes, and thermoplastic or thermosetting bonding films.

The example of FIG. 1 includes a bottom plate (102), a top plate (104), a right plate (106), and a left plate (108), the plates connected along edges (110, 111, 112, and 113) so as to define a space generally cubical in shape with four closed sides and two open ends. In the example of FIG. 1, the right plate (106) connects with the bottom plate (102) along edges (112) by the thermal interface (120). Edges (112) are the upper-rightmost edge of the bottom plate (102) and the lower-rightmost edge of the right plate (106). The left plate (108) connects with the bottom plate (102) along edges (110) by the thermal interface (120). Edges (110) are the upper-leftmost edge of the bottom plate (102) and the lower-leftmost edge of the left plate (108). The right plate (106) connects with the top plate (104) along edges (113) by the thermal interface (120). Edges (113) are the lower-rightmost edge of the upper plate (104) and the upper-rightmost edge of the right plate (106). The left plate (108) connects with the top plate (104) along edges (111) by the thermal interface (120). Edges (111) are the lower-leftmost edge of the upper plate (104) and the upper-leftmost edge of the left plate (108).

The example of FIG. 1 also includes a thermal transport (116) connected to the plate (102) receiving the thermal load and to at least one of the other plates (104, 106, and 108) so as to distribute the thermal load among the plates (102, 104, 106, and 108) of the heat sink (100). The thermal transport (116) is a heat transfer mechanism that transports thermal energy from one region along the thermal transport to another region along the thermal transport with a minimal loss of thermal energy. Such thermal transports have an efficiency that approximates a closed thermal transfer system. Examples of thermal transports include, for example, heat pipes and carbon nanotubes.

The example of FIG. 1 also includes heat-dissipating fins (122) connected to each plate (102, 104, 106, and 108), the fins spaced apart in parallel and extending from each plate (102, 104, 106, and 108) towards a central axis (114) of the heat sink. The heat-dissipating fins (122) are thermal conductors that provide additional surface area to heat sink (100) for dissipating the thermal load. The heat-dissipating fins (122) in the example of FIG. 1 connect to each plate (102, 104, 106, and 108) by extrusion. The extruded heat-dissipating fins (122) in the example of FIG. 1 are for explanation only, and not for limitation. The heat-dissipating fins (122) may also connect to each plate (102, 104, 106, and 108) by bonding the heat-dissipating fins (122) to each plate (102, 104, 106, and 108) through the use of epoxy, press-fit, brazing, welding, or other connections as may occur to those of skill in the art.

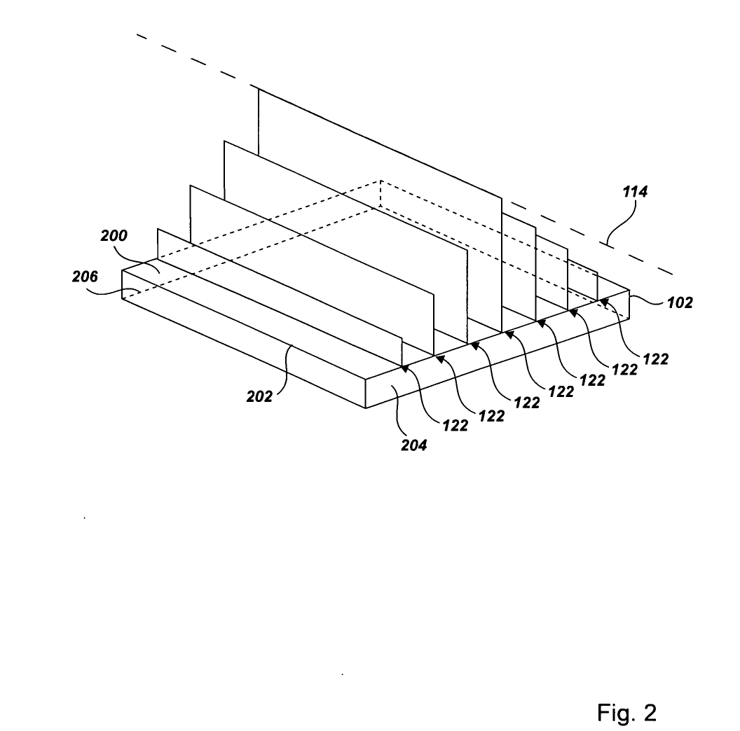

For further explanation of the heat-dissipating fins (122), FIG. 2 sets forth a perspective view of a further exemplary heat sink for distributing a thermal load according to embodiments of the present invention that includes heat-dissipating fins (122) spaced apart in parallel and orthogonally extending from one of the plates (102) toward a central axis (114) of a heat sink according to embodiments of the present invention. The depiction of the heat-dissipating fins (122) and one of the plates (102) in the example of FIG. 2 represents a bottom portion of a heat sink for distributing a thermal load. The remaining portions of the heat sink are omitted from this example for clarity of explanation.

In the example of FIG. 2, the heat-dissipating fins (122) connect to the bottom plate (102) by extrusion from the bottom plate (102). As mentioned above, extruded heat-dissipating fins are for explanation, and not for limitation. The heat-dissipating fins (122) may also connect to the bottom plate (102) by bonding the fins (122) to the bottom plate (102) through the use of epoxy, brazing, or welding.

The heat-dissipating fins (122) in the example of FIG. 2 are spaced apart in parallel and orthogonally extend from the bottom plate (102) towards a central axis (114) of the heat sink. Each heat-dissipating fin (122) extends in height from an inner bottom surface (200) of the bottom plate (102) to the plane formed by the upper-leftmost edge (202) of the bottom plate (102) and the central axis (114). The heat-dissipating fins (122) extend in length from a bottom front surface (204) to a bottom back surface (206).

In the example of FIG. 2, manufacturing capabilities may restrict the thickness of the heat-dissipating fins (122) and number of heat-dissipating fins (122) connected to bottom plate (102). While thinner fins may allow a heat sink designer to place more fins in a given space because the gaps between fins are smaller, thinner fins may also limit the height of the fins. Extruded heat-dissipating fins (122) in the example of FIG. 2 typically have fin height-to-gap aspect ratios of up to 6 and a minimum fin thickness of 1.3 millimeters. Special die design features may however increase the height-to-gap aspect ratio to 10 and decrease the minimum fin thickness to 0.8 millimeters. For example, given a maximum heat-dissipating fin (122) height of 30 millimeters and a fin height-to-gap aspect ratio of 6, the minimum gap between heat-dissipating fins (122) is calculated as follows:
G=H÷R=30÷6=5 millimeters
where G is the gap between the heat-dissipating fins, H is the height of the heat-dissipating fins, and R is the fin height-to-gap aspect ratio.

After obtaining the minimum gap between fins (122), the number of heat-dissipating fins (122) is calculated as the quantity of the width of the plate plus the gap between fins divided by the quantity of the fin thickness plus the gap. Continuing with the previous example, given a bottom plate (102) width of 60 millimeters and a fin thickness of 1.3 millimeters, the number of heat-dissipating fins (122) connected the base plate (102) is calculated as follows:
N=(W+G)÷(T+G)=(60+5)÷(5+1.3)=10.3 fins
where N is the number of heat-dissipating fins that a plate may accommodate, W is the width of the plate, G is the gap between the heat-dissipating fins, and T is the thickness of the heat-dissipating fins. This calculation for the number of fins yields 10.3 fins, meaning that in this example, the plate may accommodate 10 fins.

The heat-dissipating fins (122) connected to the top plate, the right plate, and the left plate are similar in structure to the heat-dissipating fins (122) connected to the bottom plate (102) in the example of FIG. 2. The heat-dissipating fins (122) connect to each plate such that the fins are spaced apart in parallel and extend from each plate towards a central axis (114) of the heat sink.

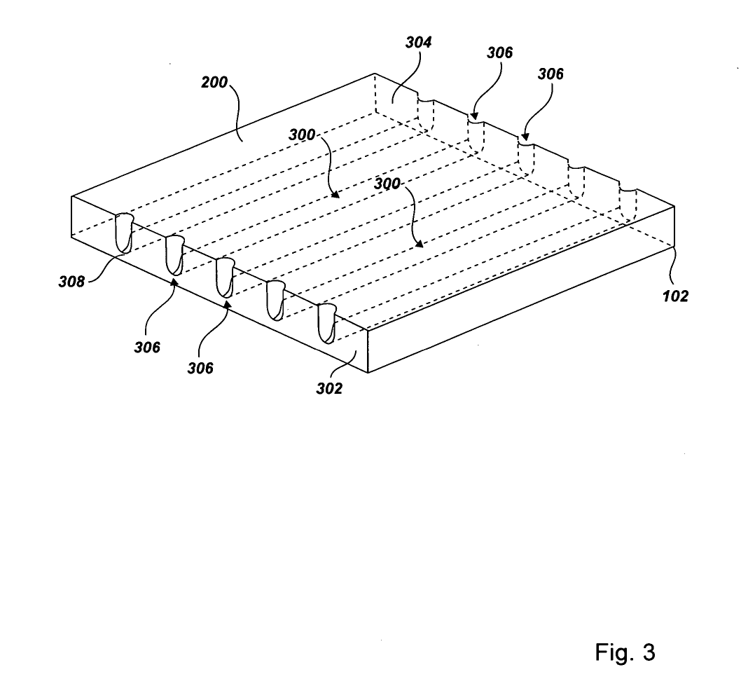

For further explanation, FIG. 3 sets forth a perspective view of a further exemplary heat sink for distributing a thermal load according to embodiments of the present invention that includes a bottom plate (102). The bottom plate (102) in the example of FIG. 3 includes lower heat pipe tunnels (300) spaced apart in parallel that receive heat pipes through the bottom plate (102). In the example of FIG. 3, the heat-dissipating fins are omitted for explanation and clarity.

In the example of FIG. 3, lower heat pipe tunnels (300) are circular tunnels that extend through the bottom plate (102) from the left surface (302) of the bottom plate (102) to the right surface (304) of the bottom plate (102). The diameter of the lower heat pipe tunnels (300) conforms to the diameter of the heat pipe received by the lower heat pipe tunnels (300). In the example of FIG. 3, the lower heat pipe tunnels (300) are spaced equally apart in parallel.

The example of FIG. 3 also includes semicircular cavities (306) along the left surface (302) of the bottom plate (102) and along the right surface (304) of the bottom plate (102). Each semicircular cavity (306) intersects one of the lower heat pipe tunnels (300), and the diameter of the semicircular cavities (306) conforms the diameter of the lower heat pipe tunnels (300). In the example of FIG. 3, the semicircular cavities (306) extend from the bottom (308) of the lower heat pipe tunnels (300) to the inner bottom surface (200) of the bottom plate (102).

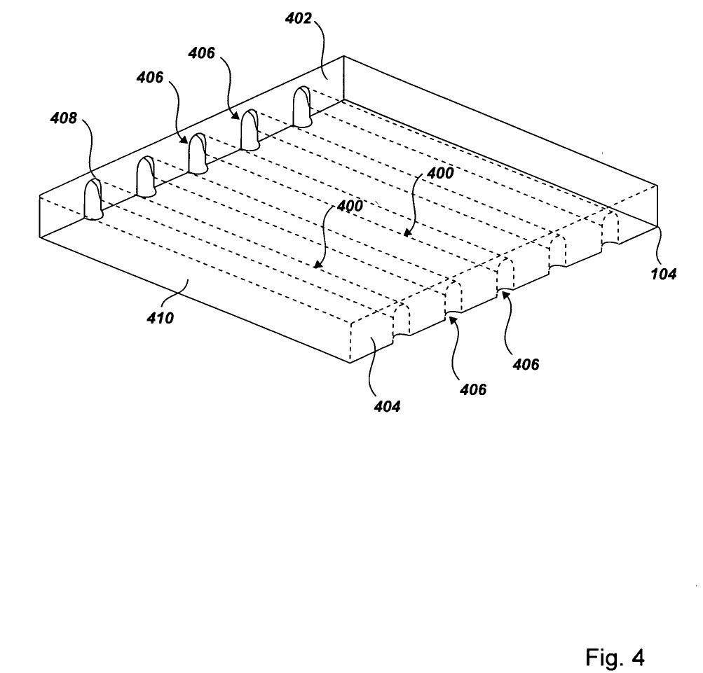

For further explanation, FIG. 4 sets forth a perspective view of a further exemplary heat sink for distributing a thermal load according to embodiments of the present invention that includes a top plate (104). The top plate (104) in the example of FIG. 4 includes upper heat pipe tunnels (400) spaced apart in parallel that receive heat pipes through the top plate, each upper heat pipe tunnel (400) corresponding to one of the lower heat pipe tunnels discussed with reference to FIG. 3. In the example of FIG. 4, the heat-dissipating fins are omitted for explanation and clarity.

In the example of FIG. 4, upper heat pipe tunnels (400) are circular tunnels that extend through the top plate (104) from the left surface (402) of the top plate (104) to the right surface (404) of the top plate (104). The diameter of the upper heat pipe tunnels (400) conforms to the diameter of the heat pipe received by the upper heat pipe tunnels (400). In the example of FIG. 4, the upper heat pipe tunnels (400) are spaced equally apart in parallel in a manner conforming to the spacing of the lower heat pipe tunnels discussed with reference to FIG. 3.

The example of FIG. 4 also includes semicircular cavities (406) along the left surface (402) of the top plate (104) and along the right surface (404) of the top plate (104). Each semicircular cavity (406) intersects one of the upper heat pipe tunnels (400), and the diameter of the semicircular cavities (406) conforms the diameter of the upper heat pipe tunnels (400). In the example of FIG. 4, the semicircular cavities (406) extend from the top (408) of the upper heat pipe tunnels (400) to an inner top surface (410) of the top plate (104).

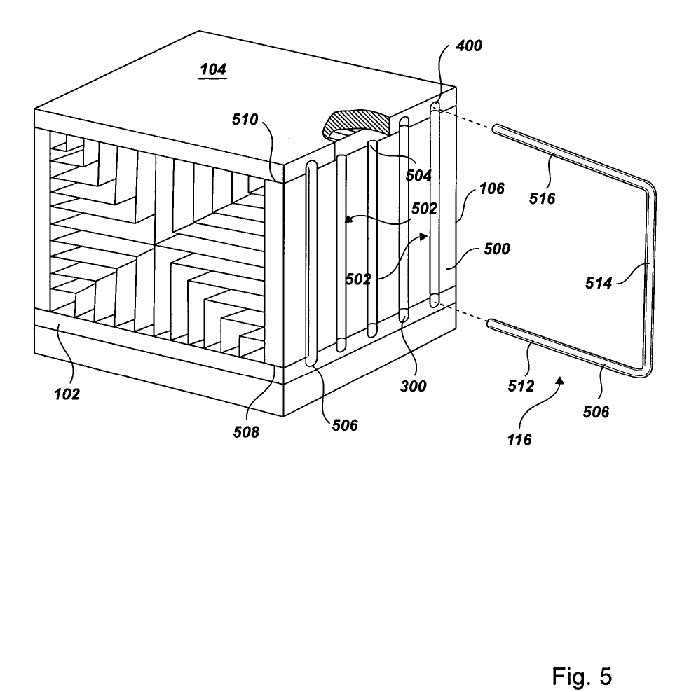

For further explanation, FIG. 5 sets forth a perspective view of a further exemplary heat sink for distributing a thermal load according to embodiments of the present invention that includes a right plate (106) and thermal transport (116). The right plate (106) in the example of FIG. 5 includes a right outer surface (500) and right heat pipe channels (502) spaced apart in parallel along the right outer surface (500), each right heat pipe channel (502) including a semicircular cavity (504) longitudinally extending from one of the lower heat pipe tunnels (300) to the corresponding upper heat pipe tunnel (400). The thermal transport (116) in the example of FIG. 5 includes a heat pipe (506) adapted to engage one of the lower heat pipe tunnels (300), one of the right heat pipe channels (502), and one of the upper heat pipe tunnels (400) so as to distribute the thermal load among the plates of the heat sink.

In the example of FIG. 5, the right heat pipe channels (502) are semicircular cavities (504) along the right outer surface (500) that extend in length from the bottom surface (508) of the right plate (106) to the top surface (510) of the right plate (106). The right heat pipe channels (502) are spaced apart in parallel along the right outer surface (500). The spacing between right heat pipe channels conforms to the spacing of the lower heat pipe tunnels (300) of the bottom plate (102) as discussed with reference to FIG. 3 and the upper heat pipe tunnels (400) of the top plate (104) as discussed with reference to FIG. 4. The diameter of the right heat pipe channels (502) in the example of FIG. 5 conforms to the diameter of the lower heat pipe tunnels (300) and the upper heat pipe tunnels (400).

In the example of FIG. 5, the heat pipe (506) is a closed evaporator-condenser system consisting of a sealed, hollow tube whose inside walls are lined with a capillary structure, also referred to as a ‘wick.’ A thermodynamic working fluid having substantial vapor pressure at the desired operating temperature saturates the pores of the wick. The fluid heats and evaporates when heat is applied to a region of the heat pipe (506). As the evaporating fluid fills the hollow center of the wick, the vapor diffuses throughout the heat pipe (506). The vapor condenses in the heat pipe (506) wherever the temperature along the heat pipe (506) falls below the temperature of the evaporation area. As the vapor condenses, the vapor gives up the heat the vapor acquired during evaporation. Capillary action within the wick returns the condensate to the evaporation area and completes the operating cycle.

In the example of FIG. 5, the heat pipe (506) is adapted to engage one of the lower heat pipe tunnels (300), one of the right heat pipe channels (502), and one of the upper heat pipe tunnels (400) so as to distribute the thermal load among the plates of the heat sink. The heat pipe (506) in the example of FIG. 5 includes a bottom section (512) that inserts into the lower heat pipe tunnel (300). The heat pipe (506) also includes a lateral section (514) adjacent to the bottom section (512). The lateral section (514) of the heat pipe (506) connects with the inner surface of the right heat pipe channel (502). The heat pipe (506) further includes a top section (516) adjacent to the right section (514). The top section (516) of the heat pipe (506) inserts into the upper heat pipe tunnel (400).

In the example of FIG. 5, the heat pipe (506) engages one of the lower heat pipe tunnels (300), one of the right heat pipe channels (502), and one of the upper heat pipe tunnels (400) by a press-fit connection. Such a press-fit connection is for example only, and not for limitation. The heat pipe (506) may also engage one of the lower heat pipe tunnels (300), one of the right heat pipe channels (502), and one of the upper heat pipe tunnels (400) by fastening mechanism such as, for example, a clip, a screw, or an adhesive.

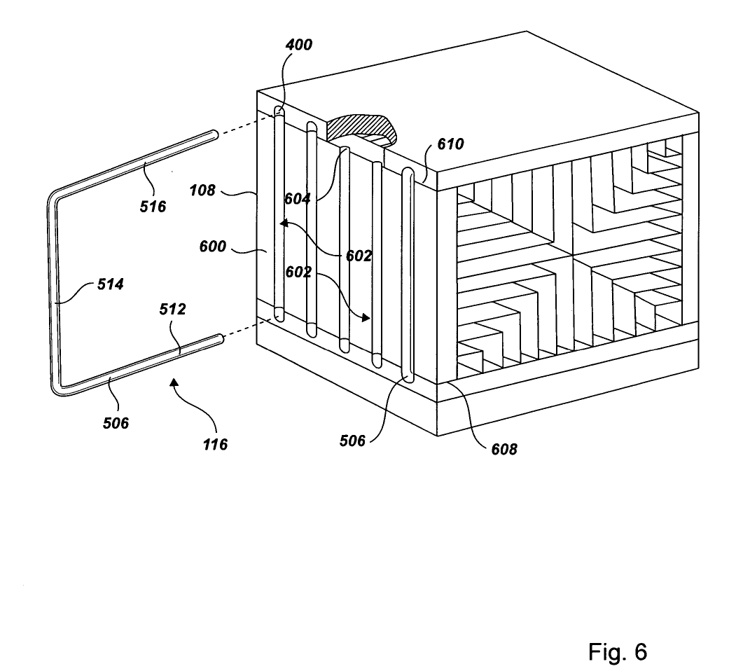

For further explanation, FIG. 6 sets forth a perspective view of a further exemplary heat sink for distributing a thermal load according to embodiments of the present invention that includes a left plate (108) and thermal transport (116) according to embodiments of the present invention. The left plate (108) in the example of FIG. 6 includes a left outer surface (600) and left heat pipe channels (602) spaced apart in parallel along the left outer surface (600), each left heat pipe channel (602) including a semicircular cavity (604) longitudinally extending from one of the lower heat pipe tunnels (300) to the corresponding upper heat pipe tunnel (400). The thermal transport (116) in the example of FIG. 6 includes a heat pipe (506) adapted to engage one of the lower heat pipe tunnels (300), one of the left heat pipe channels (602), and one of the upper heat pipe tunnels (400) so as to distribute the thermal load among the plates of the heat sink.

In the example of FIG. 6, the left heat pipe channels (602) are semicircular cavities (604) along the left outer surface (600) that extend in length from the bottom surface (608) of the left plate (108) to the top surface (610) of the left plate (108). The left heat pipe channels (602) are spaced apart in parallel along the left outer surface (600). The spacing between left heat pipe channels (602) conforms to the spacing of the lower heat pipe tunnels (300) of the bottom plate (102) as discussed with reference to FIG. 3 and the upper heat pipe tunnels (400) of the top plate (104) as discussed with reference to FIG. 4. The diameter of the left heat pipe channels (602) in the example of FIG. 6 conforms to the diameter of the lower heat pipe tunnels (300) and the upper heat pipe tunnels (400).

In the example of FIG. 6, the heat pipe (506) is adapted to engage one of the lower heat pipe tunnels (300), one of the left heat pipe channels (602), and one of the upper heat pipe tunnels (400) so as to distribute the thermal load among the plates of the heat sink. The heat pipe (506) in the example of FIG. 6 includes a bottom section (512) that inserts into the lower heat pipe tunnel (300). The heat pipe (506) also includes a lateral section (514) adjacent to the bottom section (512). The lateral section (514) of the heat pipe (506) connects with the inner surface of the left heat pipe channel (602). The heat pipe (506) further includes a top section (516) adjacent to the right section (514). The top section (516) of the heat pipe (506) inserts into the upper heat pipe tunnel (400).

In the example of FIG. 6, the heat pipe (506) engages one of the lower heat pipe tunnels (300), one of the left heat pipe channels (602), and one of the upper heat pipe tunnels (400) by a press-fit connection. Such a press-fit connection is for example only, and not for limitation. The heat pipe (506) may also engage one of the lower heat pipe tunnels (300), one of the left heat pipe channels (602), and one of the upper heat pipe tunnels (400) by fastening mechanism such as, for example, a clip, a screw, or an adhesive.

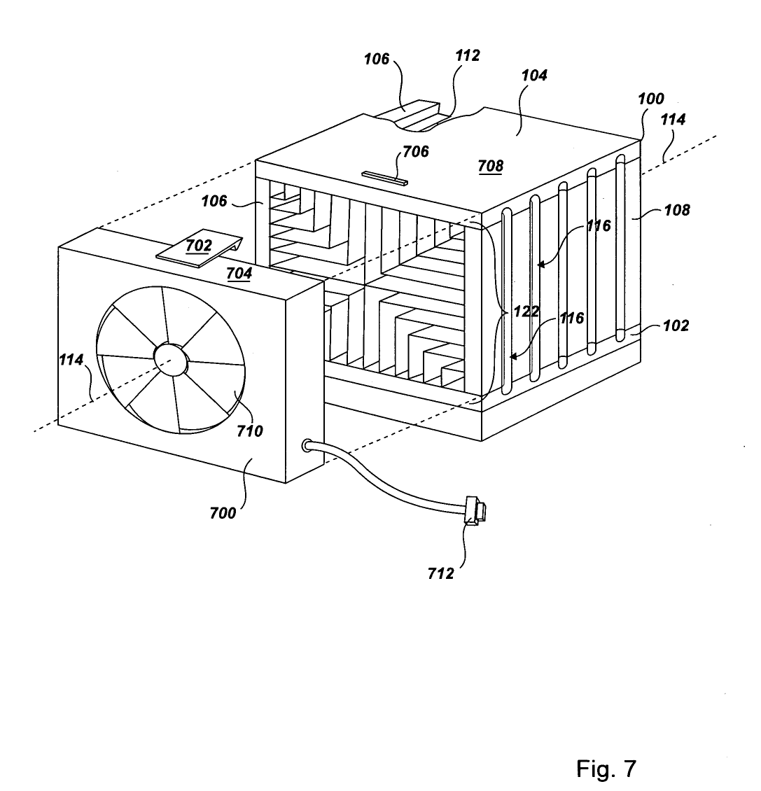

For further explanation, FIG. 7 sets forth a perspective view of a further exemplary heat sink (100) for distributing a thermal load according to embodiments of the present invention. The example of FIG. 7 includes a bottom plate (102), a top plate (104), a right plate (106), and a left plate (108), the plates connected along edges so as to define a space generally cubical in shape with four closed sides and two open ends. The example of FIG. 7 also includes heat-dissipating fins (122) connected to each plate, the fins spaced apart in parallel and extending from each plate (102, 104, 106, and 108) towards a central axis (114) of the heat sink (100). The example of FIG. 7 also includes a thermal transport (116) connected to the plate (102) receiving the thermal load and to at least one of the other plates so as to distribute the thermal load among the plates of the heat sink (100). In the example of FIG. 7, the plates (102, 104, 106, and 108), the heat-dissipating fins (122), and the thermal transport (116) are similar in structure to the plates (102, 104, 106, and 108), the heat-dissipating fins (122), and the thermal transport (116) described with reference to FIG. 1.

The example of FIG. 7 also includes a fan (700) oriented with respect to the plates (102, 104, 106, and 108) so as to induce air flow across the fins (122) along the central axis (114). In the example of FIG. 7, the fan (700) connects to heat sink (100) by clip (702) mounted on a top surface (704) of fan (700) that engages a detent (706) mounted on a top surface (708) of the top plate (104). A second clip (not shown) for connecting the fan (700) to heat sink (100) mounts on the bottom surface of the fan (700) to engage a detent (not shown) mounted on the bottom surface of the bottom plate (102). The depiction of the fan (700) connected to the heat sink (100) by a clip (702) in the example of FIG. 7 is for explanation and not for limitation. In fact, the fan (700) need not connect to the heat sink (100) at all. The fan (700) may mount to a circuit board adjacent to the heat sink (100) such that the fan (700) is oriented with respect to the plates (102, 104, 106, and 108) so as to induce air flow across the fins (122) along the central axis (114).

The fan (700) in the example of FIG. 7 induces air flow across the fins (122) along the central axis (114) by rotating fan blades (710). The fan blades (710) rotate under the power of a fan motor (not shown) that converts electrical energy to mechanical energy. The fan motor receives electrical energy from a power supply through electrical plug (712). The fan motor transmits power to the fan blades (710) through a shaft (not shown) connected with the fan blades (710) and the motor.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A heat sink for distributing a thermal load, the heat sink comprising:
a bottom plate, a top plate, a right plate, and a left plate, the plates connected along edges so as to define a space generally cubical in shape with four closed sides and two open ends;
heat-dissipating fins connected to each plate, the fins spaced apart in parallel and extending from each plate towards a central axis of the heat sink; and
a thermal transport connected to the plate receiving the thermal load and to at least one of the other plates so as to distribute the thermal load among the plates of the heat sink.

2. The heat sink of claim 1 wherein:
the bottom plate further comprises lower heat pipe tunnels spaced apart in parallel that receive heat pipes through the base plate;
the top plate further comprises upper heat pipe tunnels spaced apart in parallel that receive heat pipes through the top plate, each upper heat pipe tunnel corresponding to one of the lower heat pipe tunnels;
the right plate further comprises a right outer surface and right heat pipe channels spaced apart in parallel along the right outer surface, each right heat pipe channel comprising a semicircular cavity longitudinally extending from one of the lower heat pipe tunnels to the corresponding upper heat pipe tunnel; and
the left plate further comprises a left outer surface and left heat pipe channels spaced apart in parallel along the left outer surface, each left heat pipe channel comprising a semicircular cavity longitudinally extending from one of the lower heat pipe tunnels to the corresponding upper heat pipe tunnel.

3. The heat sink of claim 2 wherein the thermal transport further comprises a heat pipe adapted to engage one of the lower heat pipe tunnels, one of the right heat pipe channels, and one of the upper heat pipe tunnels so as to distribute the thermal load among the plates of the heat sink.

4. The heat sink of claim 2 wherein the thermal transport further comprises a heat pipe adapted to engage one of the lower heat pipe tunnels, one of the left heat pipe channels, and one of the upper heat pipe tunnels so as to distribute the thermal load among the plates of the heat sink.

5. The heat sink of claim 1 wherein the heat-dissipating fins further comprise heat-dissipating fins spaced apart in parallel and orthogonally extending from each plate toward the central axis of the heat sink.

6. The heat sink of claim 1 further comprising a fan oriented with respect to the plates so as to induce air flow across the fins along the central axis.
